(19) United States
(12) Patent Application Publication
(10) Pub. No.: US 2026/0136695 A1
(43) Pub. Date: May 14, 2026

(54) IMAGE SENSOR HAVING TRENCH ISOLATION STRUCTURE

(71) Applicant: OMNIVISION TECHNOLOGIES, INC., Santa Clara, CA (US)

(72) Inventors: Shimpei Fukuoka, Kanagawa (JP); Guannho Tsau, San Jose, CA (US)

(73) Assignee: OMNIVISION TECHNOLOGIES, INC., Santa Clara, CA (US)

(21) Appl. No.: 18/943,848

(22) Filed: Nov. 11, 2024

(51) Int. Cl. H01L 27/146

(52) U.S. Cl. CPC H10F 39/807; H10F 39/011

(57) ABSTRACT

An image sensor includes a plurality of pixels, and deep trench isolations (DTIs) formed between the plurality of pixels. The deep trench isolations include back side deep trench isolations (BDTIs) extending from a back surface of a substrate and surrounding the photodiodes and the floating diffusions of the respective pixels from outside, and front side deep trench isolations (FDTIs) extending from a front surface of the substrate and having lower ends facing part of upper ends of the BDTIs.

### TECHNICAL FIELD

The present disclosure relates to an image sensor including deep trench isolations formed between a plurality of pixels.

### BACKGROUND

In image sensors, various measures are taken for downsizing pixels. For example, a system in which three wafers of a pixel wafer for photodiode array, a transistor wafer for pixel transistor including a reset, a source follower, and row select transistors, and a logic wafer for an application-specific integrated circuits (ASIC) circuit are stacked is employed.

However, further downsizing of pixels is requested. In smaller pixels, it is difficult to balance Full Well Capacity (FWC) and blooming performance. That is, to prevent blooming between adjacent pixels within smaller pixels, FWC is set to be lower.

In order to prevent crosstalk between pixels, sufficient isolation between the adjacent pixels is requested. For the purpose, e.g., a pixel-to-pixel deep trench isolation (DTI) structure is employed. In the DTI structure, the pixels are isolated by trenches extending in the depth direction of the substrate. Here, a ground contact area is allocated proximately to the substrate surface and an opening portion is provided between the ground contact area and the DTI structure, and crosstalk is likely to occur in the region.

### SUMMARY

An image sensor according to the present disclosure includes a plurality of pixels, and deep trench isolations (DTIs) formed between the plurality of pixels, each pixel including a photodiode, a floating diffusion, and a transfer gate connecting the photodiode and the floating diffusion, the deep trench isolations including back side deep trench isolations (BDTIs) extending from a back surface of a substrate and surrounding the photodiodes and the floating diffusions of the respective pixels from outside, and front side deep trench isolations (FDTIs) extending from a front surface of the substrate and having lower ends facing part of upper ends of the BDTIs.

According to the image sensor of the present disclosure, crosstalk may be effectively suppressed by the BDTIs and the FDTIs.

### BRIEF DESCRIPTION OF DRAWINGS

Non-limiting and non-exhaustive embodiment(s) of the present disclosure will be described based on the following figures, with like or similar reference numbers are used to refer to like or similar components throughout unless otherwise specified, wherein:

FIG. 1A is a schematic plan view showing a partial structure of an image sensor according to an embodiment in accordance with the teachings of the present disclosure;

FIG. 1B is a schematic sectional view along a line X-X in FIG. 1A in accordance with the teachings of the present disclosure;

FIG. 1C is an schematic enlarged view of part A in FIG. 1B in accordance with the teachings of the present disclosure;

FIG. 1D is a schematic sectional view along a line Y-Y in FIG. 1A in accordance with the teachings of the present disclosure;

FIG. 1E is a schematic sectional view along a line Z-Z in FIG. 1A in accordance with the teachings of the present disclosure;

FIG. 2 is a schematic plan view showing a layout of four pixels of the embodiment in accordance with the teachings of the present disclosure;

FIG. 3A to FIG. 3D are schematic diagrams showing a part of a manufacturing process of the embodiment in accordance with the teachings of the present disclosure;

FIG. 4A is a schematic plan view showing a partial structure of an image sensor according to Modified Example 1 in accordance with the teachings of the present disclosure;

FIG. 4B is a schematic sectional view along a line X-X in FIG. 4A in accordance with the teachings of the present disclosure;

FIG. 4C is an schematic enlarged view of part A in FIG. 4B in accordance with the teachings of the present disclosure;

FIG. 4D is a schematic sectional view along a line Y-Y in FIG. 4A in accordance with the teachings of the present disclosure;

FIG. 4E is a schematic sectional view along a line Z-Z in FIG. 4A in accordance with the teachings of the present disclosure;

FIG. 5 is a schematic plan view showing a layout of four pixels of Modified Example 1 in accordance with the teachings of the present disclosure;

FIG. 6A to FIG. 6F are schematic diagrams showing parts of a manufacturing process of Modified Example 1 in accordance with the teachings of the present disclosure;

FIG. 7A is a schematic plan view showing a partial structure of an image sensor according to Modified Example 2 in accordance with the teachings of the present disclosure;

FIG. 7B is a schematic sectional view along a line X-X in FIG. 7A; in accordance with the teachings of the present disclosure;

FIG. 7C is a schematic sectional view along a line Y-Y in FIG. 7A in accordance with the teachings of the present disclosure;

FIG. 8A is a schematic plan view showing a partial structure of an image sensor according to Modified Example 3 in accordance with the teachings of the present disclosure;

FIG. 8B is a schematic sectional view along a line X-X in FIG. 8A in accordance with the teachings of the present disclosure;

FIG. 8C is a schematic sectional view along a line Y-Y in FIG. 8A in accordance with the teachings of the present disclosure; and

FIG. 9 is a schematic diagram showing a circuit configuration of a pixel in accordance with the teachings of the present disclosure.

### DESCRIPTION OF EMBODIMENTS

In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects. Note that the embodiment explained below does not limit the present disclosure. A configuration formed by selectively combining a plurality of illustrations is also included in the present disclosure.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### Pixel Configuration Example

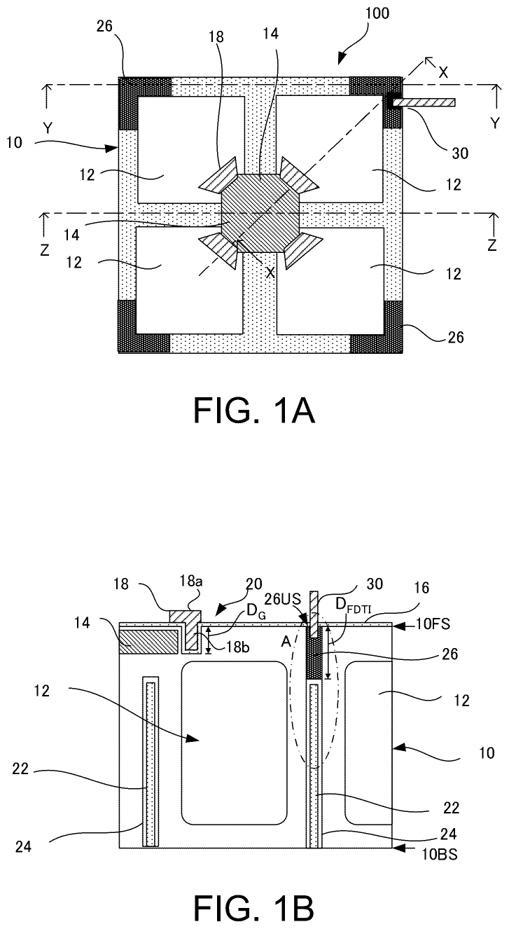

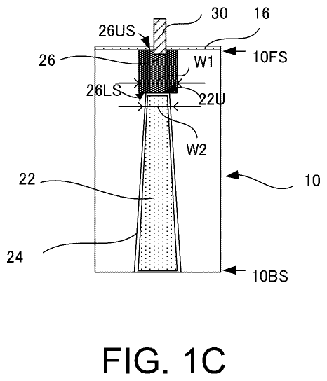

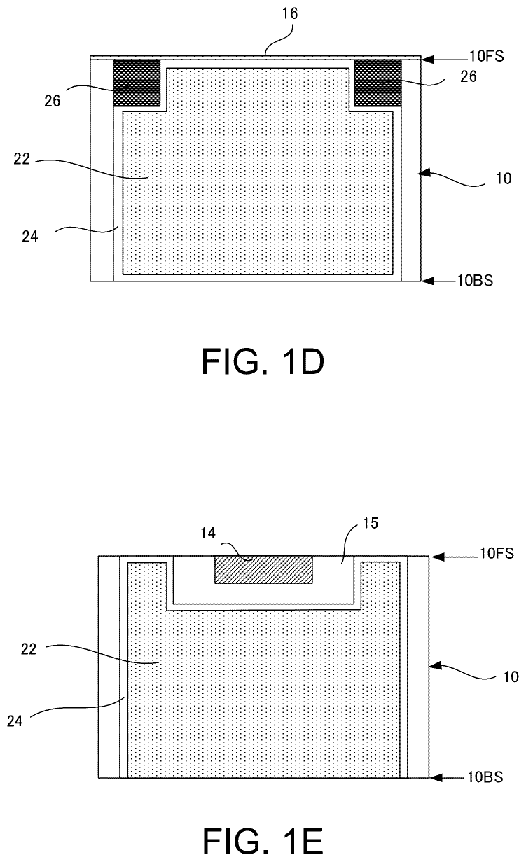

FIG. 1A to FIG. 1E show partial structures of an image sensor according to exemplary embodiment provided in accordance with the teachings of the present disclosure. FIG. 1A is a plan view of the partial structures, FIG. 1B is a sectional view along a line X-X in FIG. 1A, FIG. 1C is an enlarged view of part A in FIG. 1B, FIG. 1D is a sectional view along a line Y-Y in FIG. 1A, and FIG. 1E is a sectional view along a line Z-Z in FIG. 1A.

In the illustrated embodiment, each pixel 100 may have a square shape in the plan view and placed in a matrix formed on a semiconductor substrate 10. It is noted that in other embodiments, each pixel may have different geometric shapes such as a diamond shape, a pentagon shape, and the like depending on pixel sizes and layout requirements. In FIG. 1A to FIG. 1E, one pixel is shown exemplarily. The semiconductor substrate 10 may be for example, a silicon substrate. The semiconductor substrate 10 may has a front side surface 10FS and a backside surface 10BS opposite to the front side surface 10FS. In some embodiments, the front side surface 10FS may be referred as a non-illuminated side, while the backside surface 10BS may be referred as an illuminated side. In some embodiments, each pixel 100 may include a plurality of transfer transistors 20 coupling the plurality of photodiodes 12 to the floating diffusion region 14.

It should be noted that the term “semiconductor substrate” recited throughout the disclosure may correspond to a part of or an entirety of a semiconductor wafer (e.g., a silicon wafer). In some embodiments, the semiconductor substrate 10 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof.

The semiconductor substrate 10 may correspond to any semiconductor material or combination of materials that may be doped or otherwise configured to facilitate the formation of an integrated circuit (e.g., forming individual circuitry components such as source/drain regions of transistors, memory elements, photodiodes, or the like).

In the present embodiment, the photodiodes 12 may be formed from junction of two impurity-doped regions having two conductivity types (n-type and p-type) within the semiconductor substrate 10. In one embodiment, the semiconductor substrate 10 is the p-type. The photodiode 12 includes an n-type photodiode doped region formed or otherwise disposed proximately to the front side surface 10FS. In such an example, the photodiode 12 may be referred as a n-type photodiode. In the present disclosure, the n-type may be referred to as “first conductivity type”, and the p-type may be referred to as “second conductivity type”. The n-type photodiode doped region of photodiode 12 may correspond to a photoelectric conversion region that generates electric charges (in the present embodiment, e.g., electrons) in accordance with incident light.

In the illustrated example, a plurality of photodiodes 12 (e.g., four photodiodes 12) are formed within a region of each pixel 100 sharing a common floating diffusion region, e.g., the floating diffusion region 14. The plurality of photodiodes 12 may be disposed under a common color filter and a common microlens. The floating diffusion region 14 is formed or otherwise disposed in the upper portion of the semiconductor substrate 10 proximately to the front side surface 10FS. The floating diffusion region 14 may be formed in a center region of the pixel 100. The floating diffusion region 14 is a doped region of the same conductivity type (e.g., n-type) as that of the photodiode doped region of the photodiode 12. A surface portion of the floating diffusion region 14 may have a higher concentration as contacts and/or metal wiring are connected thereto. The floating diffusion region 14 may be configured to have a predetermined capacitance for storing charges (e.g., electrons or holes) transferred from the photodiode 12.

A transfer gate 18 of each transfer transistor 20 included in the plurality of transistors 20 is disposed on the front surface side 10FS of the semiconductor substrate 10. An insulating film 16 is formed on the front side surface 10FS of the semiconductor substrate 10. The insulating film 16 may be formed of an oxide-based dielectric material such as silicon oxide. The insulating film 16 may be disposed between the transfer gate 18 and the front surface side 10FS of the semiconductor substrate 10. The insulating film 16 may function as a gate oxide film of transfer transistor 20, which will be described in following paragraphs.

On the semiconductor substrate 10 disposed between the floating diffusion region 14 and the photodiodes 12, a plurality of transfer gates 18 are provided, and the parts thereof form the transfer transistor 20. In the present embodiment, the transfer gate 18 includes a horizontal gate portion 18a disposed on the front side surface 10FS of the semiconductor substrate 10 and a vertical gate portion 18b extending from the horizontal gate portion 18a by a gate depth into the semiconductor substrate 10 toward the photodiode 12 along a lateral side portion of the floating diffusion region 14. The transfer gate 18 may be formed of a conductive material such as a polysilicon material. Further, the lower surface of the horizontal gate portion 18a and the side surface and the bottom surface of the vertical gate portion 18b are electrically isolated from substrate regions of the semiconductor substrate 10 by the insulating film 16. The transfer gate having both the horizontal gate portion 18a and the vertical gate portion 18b may be referred to as a vertical transfer gate.

In an alternative embodiment, the transfer gate 18 contacts the semiconductor region between the photodiode 12 and the floating diffusion region 14 via the insulating film 16. Upon biasing with a control voltage, the transfer gate 18 may apply a predetermined electric field to the semiconductor region between the photodiode 12 and the floating diffusion region 14. When the photodiode doped region of the photodiode 12 and the floating diffusion region 14 are n-type regions and the semiconductor region therebetween is a p-type region, the semiconductor region functions as a channel region of the transfer transistor 20. Therefore, a bias voltage to the transfer gate 18 is controlled, and thereby, a current from the photodiode 12 to the floating diffusion region 14 is controlled.

As shown in FIG. 1A, it is appreciated that the four transfer gates 18 may be respectively disposed between the four photodiodes 12 and the shared floating diffusion region 14. Each of four transfer gates 18 is configured to couple each respective photodiode 12 to the floating diffusion region 14, and electric charge transport from each of the four photodiodes 12 to the one floating diffusion region 14 is independently controlled.

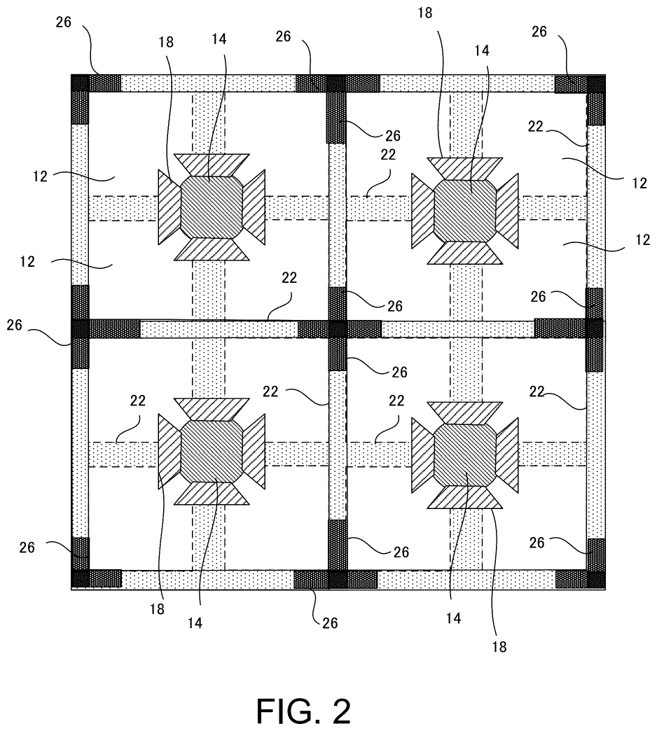

Further, FIG. 2 is a plan view showing a layout of four pixels 100 of the embodiment, in accordance with the teachings of the present disclosure. Referring to FIG. 2, the backside deep trench isolations (BDTIs) 22 are disposed to surround the photodiodes 12. In embodiments, each of the BDTIs 22 includes a trench formed from the backside surface 10BS, and the trench (or the backside trench) is at least partially filled with an insulating material (e.g., silicon oxide) for separating adjacent photodiodes within the semiconductor substrate 10. In some embodiments, the trench may be filled with conductive material or a combination of insulating material and conductive material.

As shown in FIG. 2, in the present embodiment, the parts of BDTIs 22 located in the four corners of the pixel 100 extend from the backside surface 10BS of the semiconductor substrate 10 into the semiconductor substrate 10 and terminate in positions at predetermined distances apart from the front side surface 10FS (referring to FIG. 1B). That is, the portions of the BDTIs 22 in the four corners are partial BDTIs having partial depths. In an alternative embodiment, the portions of the BDTIs 22 in the four corners of the pixel 100 having depths being less than a substrate thickness of the semiconductor substrate 10. In such an embodiment, the BDTIs 22 may be referred to as partial BDTIs. In some embodiments, the substrate thickness may range from 2.5 micrometers to 7 micrometers.

Further, referring to FIG. 1B to FIG. 1E, in some embodiments, a high-κ dielectric layer 24 covering the filling material is formed as a protective layer lining the trench inner surface of the backside trench of the BDTI 22. The high-κ dielectric layer 24 may be disposed to surround the filling material (e.g., oxide-based dielectric material). The high-κ dielectric layer 24 may include one or more material layers and function as an anti-reflection layer preventing reflection of light. The high-κ dielectric layer 24 may be formed of one or more high κ material, such as aluminum oxide, hafnium oxide, tantalum oxide configured with an appropriate thickness. In some other embodiments, the backside trenches for BDTIs 22 may be completely filled with an insulating material (e.g., silicon oxide).

Referring to FIG. 1A, the BDTIs 22 may include portions surrounding the four photodiodes 12 of the pixel 100 defining a pixel region of pixel 100 and portions located between the adjacent photodiodes 12 within the pixel 100.

In the portions facing the BDTIs 22 having the partial depths in the four corners of the one pixel 100, the front side trench isolations (FDTIs) 26 are formed. The FDTIs 26 extend from the front side surface 10FS of the semiconductor substrate 10 into an interior portion of the semiconductor substrate 10. Referring to FIG. 1C, the FDTIs 26 in the four corners of the one pixel 100 may be disposed to end on (or landed on) the upper ends 22U of the BDTIs 22. The lower end surfaces 22LS of the FDTIs 26 may be in direct contact with the upper end surfaces of the high-κ dielectric layer 24 on the upper end surfaces of the BDTIs 22. It is noted that the FDTI 26 includes a trench, and the trench is filled with polysilicon material doped with an impurity of the same conductivity type (the p-type in the example) as that of the semiconductor substrate 10 at a higher impurity concentration.

In embodiments, referring to FIG. 1B, the vertical gate portion 18b has a gate depth D_{G} that is less than a front isolation depth D_{FDTI} of the FDTI 26 with respect to front side surface.

Referring to FIG. 1B, a contact 30 is connected to a part of the upper surface 22US of the FDTI 26. The contact 30 may be coupled to a predetermined power supply for receiving a supply voltage, e.g., a ground reference voltage. In an illustrated embodiment of FIG. 1A, the contact 30 is coupled to only one of the FDTIs 26. However, it is noted that, in other embodiments, the four FDTIs 26 may be respectively connected to the predetermined power supply (e.g. ground) through respective contacts 30.

As described above, the BDTIs 22 are further formed in the peripheral edge of the one pixel 100. As shown in FIG. 1D, the BDTIs 22 located in the four corners of the one pixel 100 are the BDTIs having the partial depths. On the other hand, as shown in FIG. 1D and FIG. 1E, the BDTIs 22 may be full-depth BDTIs extending to the front side surface 10FS in the other portions than the four corners of the pixel 100. In other words, the BDTIs 22 may have variation its depths with respect to backside surface 10BS. Alternatively, portions of the BDTIs 22 located in corner regions of the one pixel 100 has the depths less than the substrate thickness semiconductor substrate 10, and portions of the BDTIs 22 in non-corner regions of the one pixel 100 has depths substantially the same as the substrate thickness semiconductor substrate 10. Further, as shown in FIG. 1D, the side surfaces of the full-depth BDTIs 22 in the four corners of the one pixel 100 may be in direct contact with the FDTIs 26 in the four corners. The full-depth BDTI or fill BDTI herein may be referred to as the BDTI having a depth that is substantially the same as the substrate thickness of the semiconductor substrate 10. The periphery of the one pixel 100 is partitioned from the adjacent pixels 100 collectively by the BDTIs 22 and the FDTIs 26 from the front side surface 10FS to the backside surface 10BS of the substrate 10. Namely, the BDTIs 22 and the FDTIs 26 collectively define the pixel region of pixel 100 and separate pixel 100 from adjacent pixels 100 included in a pixel array.

The floating diffusion region 14 is formed in the upper portion of the semiconductor substrate 10 and in the center part of the pixel 100. The BDTIs 22 located between the floating diffusion region 14 and the backside surface 10BS have the partial depths of the semiconductor substrate 10. The semiconductor region is located between the floating diffusion region 14 and the respective portions or segment of BDTIs 22.

Referring to FIG. 1D, as described above, in the instant embodiment, the FDTIs 26 arranged in a vertical direction of the semiconductor substrate 10 with respect to the BDTIs 22 are provided above the BDTIs 22 while surrounding the pixel 100. That is, the FDTIs 26 may be arranged between the BDTIs 22 and the front side surface 10FS of the semiconductor substrate 10. Thereby, the periphery of the one pixel 100 is partitioned from the adjacent pixels 100 by the full BDTIs 22 and a combination of a partial BDTIs 22 and the FDTIs 26. Therefore, occurrence of crosstalk and blooming with the adjacent pixels 100 may be effectively suppressed.

Referring to FIG. 1C, a cross-sectional width W2 of the upper end portion of the partial BDTI 22 is formed to be smaller than a cross-sectional width W1 of the lower end portion of the FDTI 26. Thereby, the lower end portion of the FDTI 26 and the upper end portion of the partial BDTI 22 are formed to be in contact with each other during forming process for improving process overlay windows.

In the current embodiment, the FDTIs 26 are provided, which is connected to the ground by the contact 30. Moreover, instead of the FDTI 26, a p-type doped region (e.g., a low-concentration p-doped region), which may be referred as a pp region, for connecting to the ground may be provided in the portion of the front side surface 10FS above the partial BDTI 22. In the present embodiment, crosstalk between the pixels is prone to be occurred in the region between the pp region and the partial BDTI 22.

The impurity concentration (ions/cm³) in the pp region is on an order of 1e¹⁷/cm³ to 1e¹⁹/cm³ higher than the impurity concentration of the semiconductor substrate 10. The impurity concentration of the FDTI 26 may be set to be higher than that in the pp region.

In the present embodiment, the filling materials filling the trenches are different between the BDTI 22 and the FDTI 26. For example, each of the BDTIs 22 is filled with the insulating material (e.g., oxide-based material). In some other embodiments, the FDTI 26 may be filled with a conductive material (e.g., doped polysilicon material or metal material) capable of receiving supply voltage.

As shown in FIG. 2, the FDTIs 26 are provided to surround the corners of the pixel region of the respective pixels 100 within the four corners of the respective pixels 100, and the contacts 30 are formed respectively on the FDTIs 26.

The full BDTIs 22 having the full depths are provided between the pixel 100 and the pixel 100 and the FDTIs 26 are provided in the four corner portions (four corners located in diagonal direction of pixel 100) of the respective pixels 100.

### Manufacturing Process

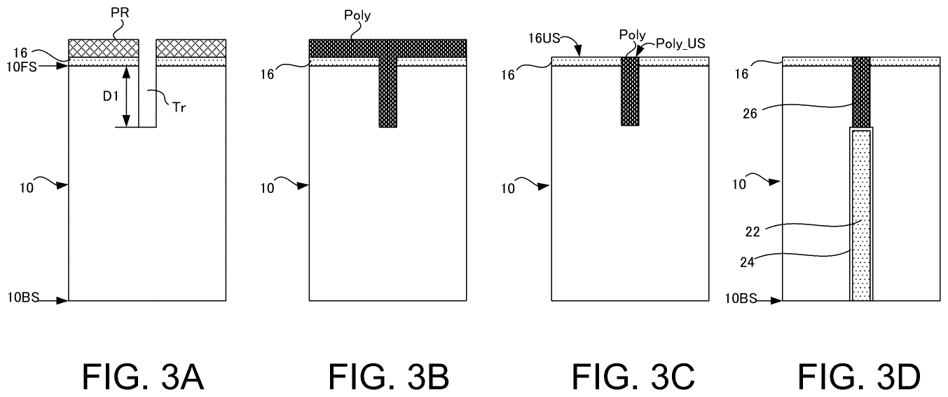

FIG. 3A to FIG. 3D show a part of a manufacturing process in accordance to the teachings of the present disclosure. Firstly, referring to FIG. 3A, a trench Tr for the FDTI 26 is formed, for example at corner regions of a pixel by a photolithography process. In one embodiment, a photoresist PR is formed on the insulating film 16 of the semiconductor substrate 10 and patterned by the photolithography process. Then, the trench Tr for forming the FDTI 26 is formed by an etching process and by removing substrate material of the semiconductor substrate 10 via a plasma dry and/or a wet etching process. The trench Tr for the FDTI 26 may extend from the front side surface 10FS in a depth D1 into the semiconductor substrate 10.

Subsequently, referring to FIG. 3B, the photoresist PR is removed and polysilicon material Poly is deposited from front side surface 10FS of the semiconductor substrate 10 into the trench Tr. Thereby, the polysilicon material Poly is deposited on the insulating film 16 and within the trench Tr. In the present embodiment, the polysilicon material Poly may be a doped polysilicon material e.g., a polysilicon material doped with p-type impurities.

Referring to FIG. 3C, the polysilicon material Poly is removed by the etching process, and thus the insulating film 16 is subsequently exposed. As shown in FIG. 3C, the height of an upper surface Poly_US of the polysilicon within the trench Tr may be equal to a vertical thickness of the insulating film 16. In some embodiment, the upper surface Poly_US of the polysilicon material Poly within the trench Tr may be levelled with an upper surface 16US of insulating film 16.

Thereafter, various steps of forming the transfer gate 18, the floating diffusion region 14, source and drains regions and gates of other pixel transistors (e.g., source follower, reset transistor, row select transistors, and the like to form pixel circuitry) are performed (not shown). Referring to FIG. 3D, a backside trench is formed by predetermined patterning from the back side surface 10BS and by removing backside substrate material of the semiconductor substrate 10 through the etching process. The backside trench may be vertically aligned with FDTI 26. The backside trench may extend from the backside surface 10BS toward the front side surface 10BS and in a direct contact with the FDTI 26. The BDTI 22 is then formed by formation of the high-κ dielectric layer 24 lining backside trench and by filling of the backside trench with the insulating material, for example, through a deposition process.

It is noted that preparation of the semiconductor substrate 10 may be performed by a conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is further noted that the described techniques are merely demonstrative and not exhaustive and that other techniques may be utilized to fabricate one or more components of various embodiments of the disclosure. Therefore, explanation thereof is omitted.

### MODIFIED EXAMPLE 1

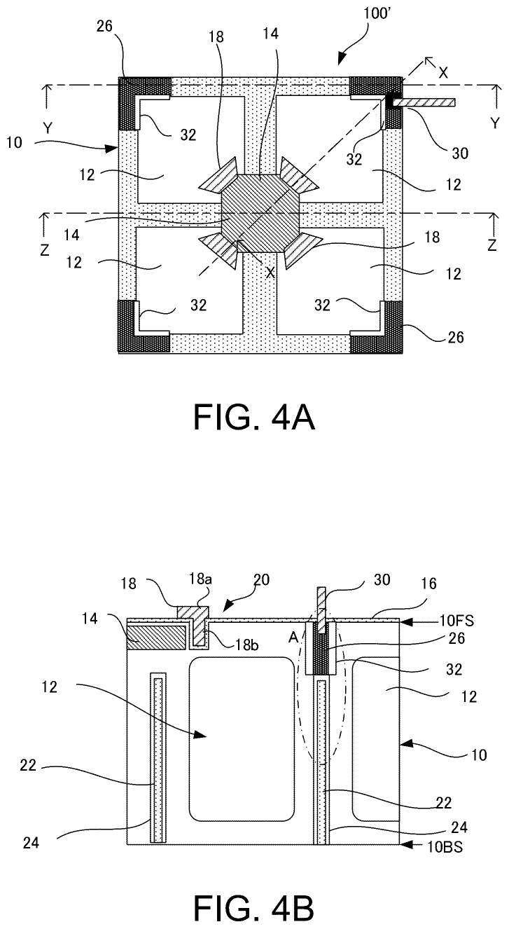

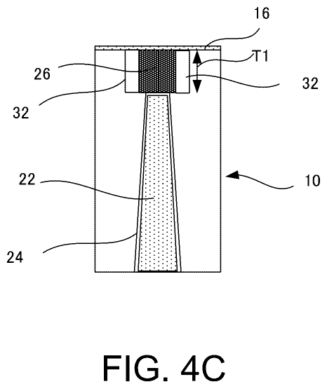

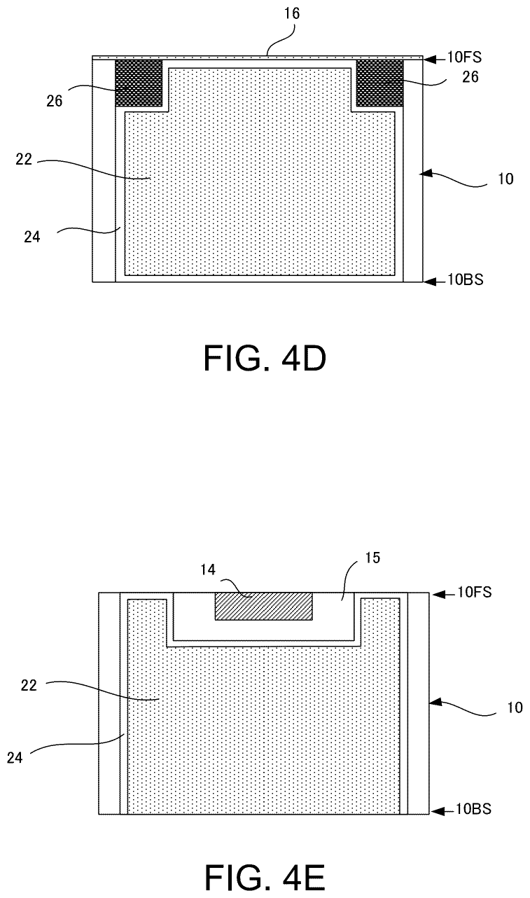

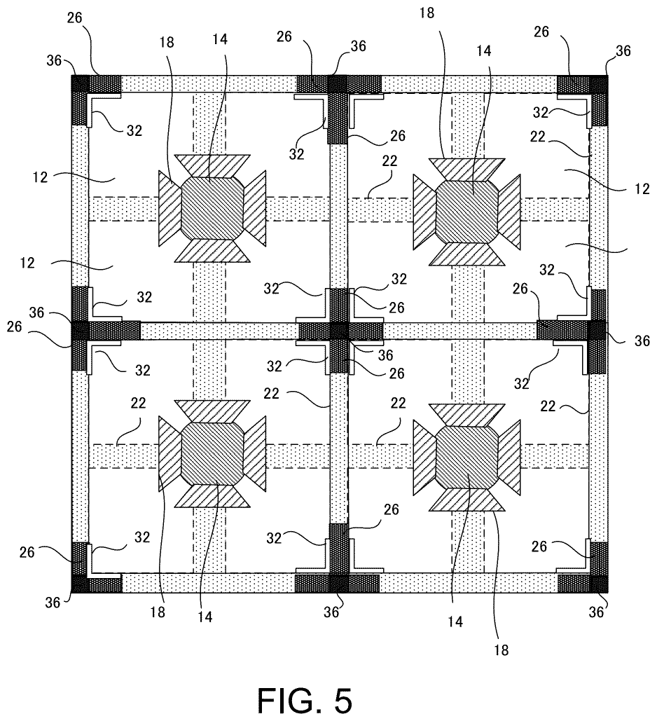

Modified Example 1 of the embodiment is explained. FIG. 4A to FIG. 4E may correspond to FIG. 1A to FIG. 1E, and FIG. 5 may correspond to FIG. 2 in accordance to the teachings of the present disclosure. Similarly named and numbered elements referenced below are coupled and functioned similar to as described above. It should be noted that pixel 100′ in FIG. 4A to FIG. 4E shares many similarities with top and cross-sectional views of pixel 100 depicted in FIG. 1A to FIG. 1E. Referring to FIG. 5, FIG. 5 provides a top view of multiple pixels 100′ arranged in into rows and column manner, which shares many similarities with the top view of pixel 100 depicted in FIG. 2. As such, it is appreciated that the differences between pixel 100 and 100′ will be described in detail herein for the sake of brevity and in order to avoid obscuring the teachings of the present invention.

In Modified Example 1, pixel 100′ further includes low-concentration impurity-doped regions 32 disposed in parts of the FDTIs 26 formed in the corner portions corresponding to the inner sides of the pixel 100′. The low-concentration impurity-doped regions 32 may be formed or otherwise disposed between respective photodiode doped region of photodiode 12 and respective portion of FDTI 26 as illustrated in FIG. 5. The low-concentration impurity-doped regions 32 may laterally extend from a respective portion of FDTI 26 in a shallow width toward respective photodiode 12. Such configuration may provide passivation to sidewall surfaces of FDTI 26 without causing a much impact on full well capacity of the nearby photodiode 12. In the present embodiment, an impurity of the same p-type as that of the polysilicon material Poly of FDTI 26 (e.g., boron (B)) may be doped in the low-concentration impurity-doped region 32. The low-concentration impurity-doped region 32 may have a conductive type opposite to that of the photodiode doped region of photodiode 12. The low-concentration impurity-doped region 32 may be coupled to ground. In some embodiments, referring to FIG. 5, the low-concentration impurity-doped region 32 may be coupled to the FDTI 26 to receive a ground reference voltage. With the FDTIs 26 surrounded by low-concentration impurity-doped regions 32, crosstalk between photodiode of same or different color can be enhanced, while enabling trench surfaces passivation and providing ground connection for ground contact 36.

Referring to FIG. 4C, a thickness T1 of the low-concentration impurity-doped region 32 along depthwise direction of the semiconductor substrate 10 is about 30 nm to 60 nm. The low-concentration impurity-doped region 32 covers the side surface of the FDTI 26 at the pixel side for being a side wall of the FDTI 26. That is, the low-concentration impurity-doped region 32 of the conductivity type (e.g., the p-type) opposite to the conductivity type (e.g., the n-type) of the photodiode doped region photodiode 12 is placed to cover the side surface of the FDTI 26. In some embodiments, the low-concentration impurity-doped region 32 may be disposed or otherwise formed to surround the FDTI 26 passivating side surfaces of the FDTI 26 in the semiconductor substrate 10. The impurity concentration of the low-concentration impurity-doped region 32 may be higher than an impurity concentration of the semiconductor substrate 10 and lower than an impurity concentration of impurity doped polysilicon material of FDTI 26. In an embodiment, the impurity concentration of the low-concentration impurity-doped region 32 may be on the order ranging from 1e17ions/cm³ to 1e19ions/cm³.

### Manufacturing Process

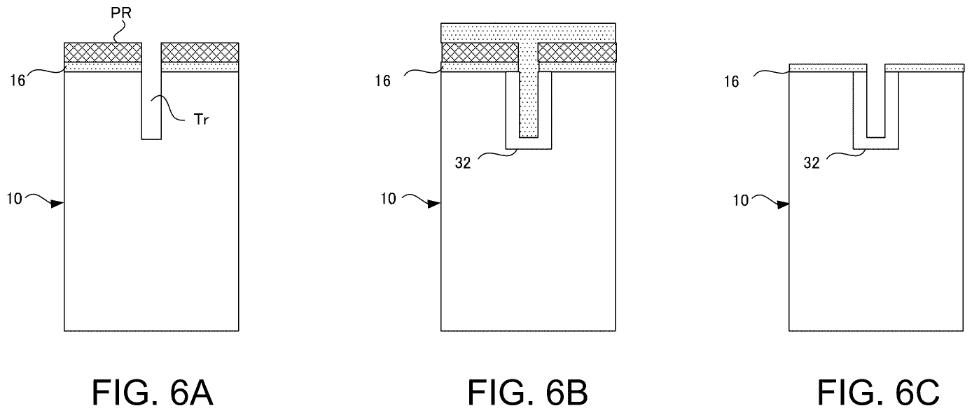

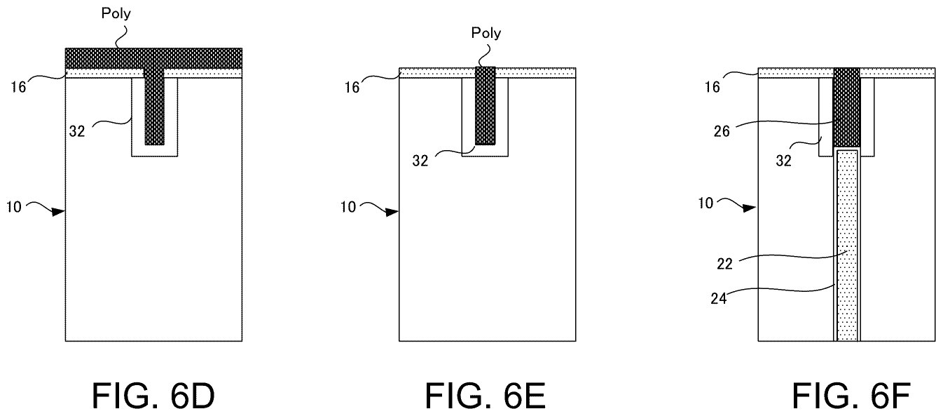

FIG. 6A-FIG. 6F show parts of a manufacturing process in accordance to the teachings of the present disclosure. The manufacturing process is different from that in FIG. 3 where the low-concentration impurity-doped region 32 is formed.

Referring to FIG. 6A and FIG. 6B, after the trench for the FDTI 26 is formed, the trench Tr is filled with a material for a solid-phase diffusion process, e.g., filled with an oxide material doped with impurity. Then, the impurity is diffused into substrate regions around the trench Tr within the semiconductor substrate 10 by an annealing process. It is noted that the low-concentration impurity-doped region 32 may be formed not by the solid-phase diffusion process, instead by a plasma doping process, an epitaxial growth process by in-situ doping, or the like.

Referring to FIG. 6C, the oxide material for solid-phase diffusion and the photoresist PR are removed. Referring to FIG. 6D to FIG. 6F, the FDTI 26 and the BDTI 22 are formed in the same manner as that in FIG. 3. The FDTI 26 and the BDTI 22 collectively provide isolation between photodiode doped region of adjacent photodiodes and define a pixel region of pixel 100′.

### MODIFIED EXAMPLE 2

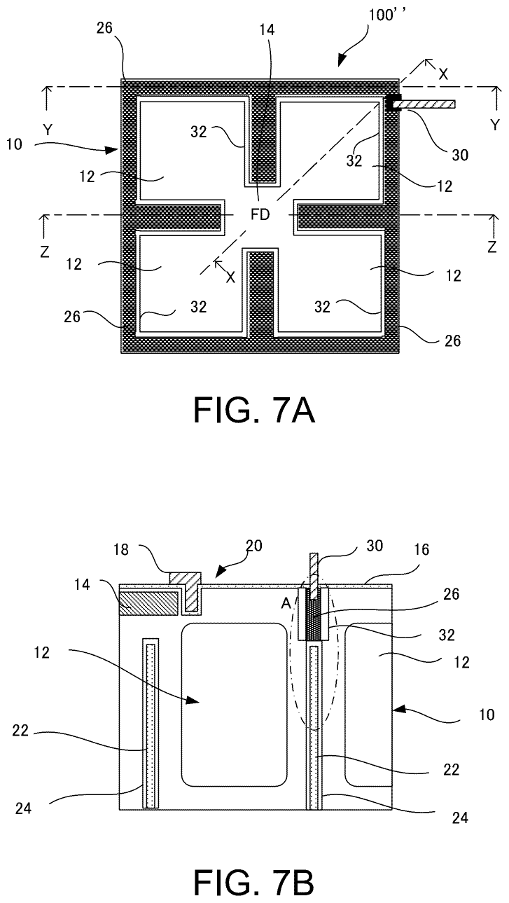

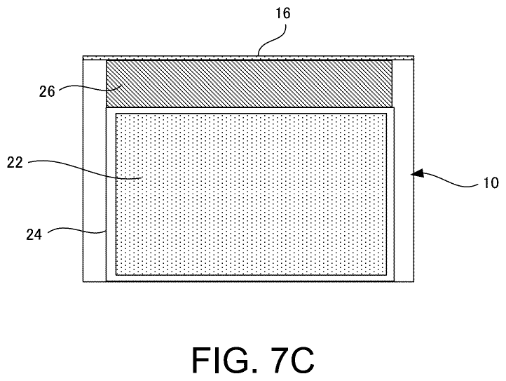

FIG. 7A, FIG. 7B, and FIG. 7C show a configuration of Modified Example 2 and respectively correspond to FIG. 1A, FIG. 1B, and FIG. 1D. Similarly named and numbered elements referenced below are coupled and function similar to as described above. It should be noted that pixel 100Δ in FIG. 7A, FIG. 7B, and FIG. 7C share many similarities with top and cross-sectional views of pixel 100 depicted FIG. 1A, FIG. 1B, and FIG. 1D. As such, it is noted that the differences between pixel 100 and 100″ will be described in detail herein for the sake of brevity and in order to avoid obscuring the teachings of the present invention.

In Modified Example 2, referring to FIG. 7A, in a pixel 100″, all BDTIs 22 are BDTIs having partial depths, and the FDTIs 26 are formed thereon between BDTIs 22 and front side surface 10FS. In the pixel 100″, each photodiode region is surrounded by a stack isolations structure of the BDTIs 22 and the FDTI 26. Therefore, the photodiodes 12 are surrounded by walls along which the BDTIs 22 and the FDTIs 26 are vertically aligned and stacked except the portions of the photodiodes 12 adjacent to the floating diffusion region 14. The side surface of the FDTI 26 is further covered by the low-concentration impurity-doped region 32. In an alternative embodiment, the FDTI 26 is surrounded by a low-concentration impurity-doped region 32. In the present embodiment, an impurity of the same p-type as that of the FDTI 26 e.g., boron (B) is doped in the low-concentration impurity-doped region 32.

In the configuration mentioned above, crosstalk between the pixels may be suppressed, and crosstalk between the four photodiodes 12 may be suppressed.

### MODIFIED EXAMPLE 3

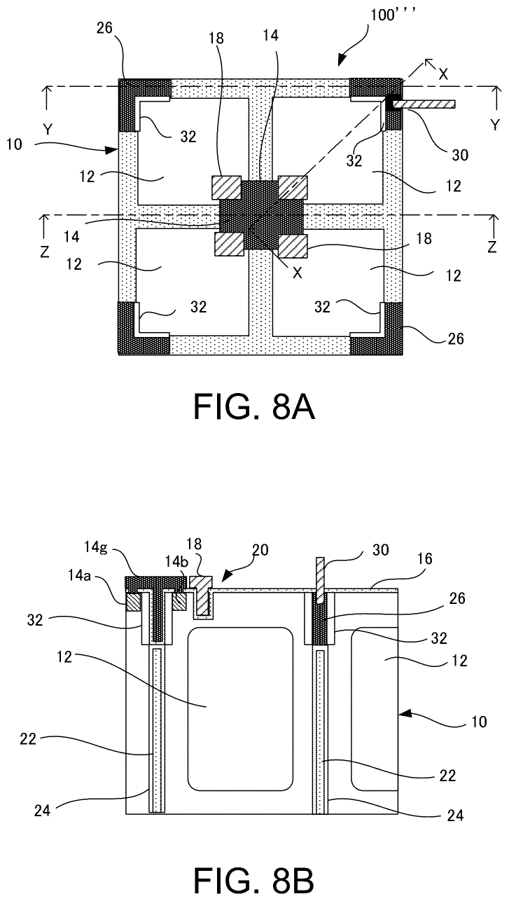

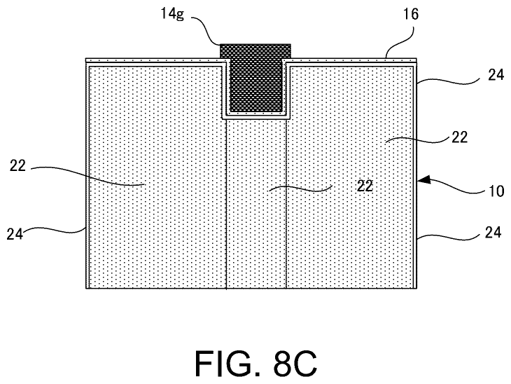

FIG. 8A, FIG. 8B, and FIG. 8C show a configuration of pixel 100′″ in a Modified Example 3 in accordance to teachings of present disclosure. Similarly named and numbered elements referenced below are coupled and function similar to as described above. It is appreciated that pixel 100″ shown in FIG. 8A, FIG. 8B and FIG. 8C shares many similarities with top and cross-sectional views of pixel 100 depicted FIG. 1A, FIG. 1B, and FIG. 1D. As such, it is noted that the differences between pixel 100 and 100′″ will be described in detail herein for the sake of brevity and in order to avoid obscuring the teachings of the present invention.

In the present embodiment of pixel 100′″, the floating diffusion region 14 may be partitioned or sub-divided into quartered, for example by the FDTI 26. In the embodiment, the floating diffusion region 14 is formed of individual sub-floating diffusion parts 14a, 14b, 14c, 14d located in each sub pixel region of pixel 100′″.

Referring to FIG. 8B and FIG. 8C, the gate electrodes 14g are disposed to couple the floating diffusion regions 14a, 14b, 14c, 14d to form the floating diffusion region 14. In the illustrated embodiments, the four sub-floating diffusion parts 14a, 14b, 14c, 14d are respectively connected to the gate electrodes 14g. The gate electrode 14g may be formed by doping of an impurity in a polysilicon material. Further, the FDTIs 26 may be formed by extension of parts of the electrodes 14g between the floating diffusion parts 14a, 14b, 14c, 14d. Provision of the low-concentration impurity-doped region 32 on the side surface of the FDTI 26 is the same as that of the above described Modified Example 2.

Further, in the present embodiment, the electrodes 14g of the floating diffusion region 14 and the FDTIs 26 connected thereto are covered by the insulating film 16.

### Circuit Configuration

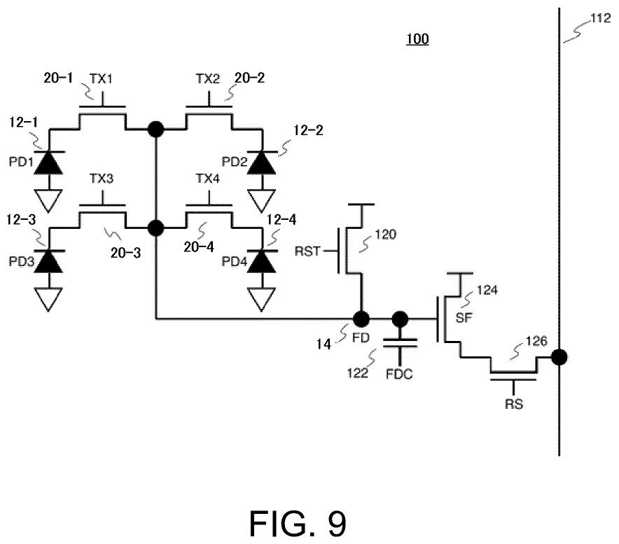

FIG. 9 illustrates one example of an exemplary schematic of pixel 100 which is included in an imaging system with an array of photodiodes including phase detection autofocus photodiodes interspersed among binned image sensing photodiodes in accordance with the teachings of the present invention. It is noted that the pixel 100 of FIG. 1B, pixel 100′ of FIG. 4A, pixel 100″ of pixel 7A, and pixel 100′″ of pixel 8A may be an example of a pixel 100 of the image sensor shown in FIG. 1A, and that similarly named and numbered elements described above are coupled and function similarly below.

In the embodiment depicted in FIG. 1B, the pixel 100 includes a photodiode 12-1 coupled to a transfer transistor 20-1, a photodiode 12-2 coupled to a transfer transistor 20-2, a photodiode 12-3 coupled to a transfer transistor 20-3, and a photodiode 12-4 coupled to a transfer transistor 20-4. A floating diffusion region 14 is coupled to transfer transistor 20-1, transfer transistor 20-2, transfer transistor 20-3, and transfer transistor 20-4. In various examples, an optional floating diffusion capacitance control signal FDC may also be included and is to be coupled to a capacitor 122, which is coupled to the floating diffusion region 14. In one example the floating diffusion capacitance control signal FDC may be utilized to provide a boost control signal to the capacitors 122 coupled to the floating diffusion region 14 as shown in FIG. 9.

The transfer transistor 20-1 is coupled to be controlled in response to a transfer control signal TX1, the transfer transistor 20-2 is coupled to be controlled in response to a transfer control signal TX2, the transfer transistor 20-3 is coupled to be controlled in response to a transfer control signal TX3, and the transfer transistor 20-4 is coupled to be controlled in response to a transfer control signal TX4. As such, the charge photogenerated in photodiode 12-1 in response to incident light is transferred to the floating diffusion region 14 in response to the transfer control signal TX1. The charge photogenerated in photodiode 12-2 in response to incident light is transferred to the floating diffusion region 14 in response to the transfer control signal TX2. The charge photogenerated in photodiode 12-3 in response to incident light is transferred to the floating diffusion region 14 in response to the transfer control signal TX3. The charge photogenerated in photodiode 12-4 in response to incident light is transferred to the floating diffusion region 14 in response to the transfer control signal TX4.

As illustrated in the depicted example of FIG. 9, a reset transistor 120 is coupled between a voltage supply (e.g., AVDD) and the floating diffusion region 14. A gate of a source follower transistor 124 is coupled to the floating diffusion region 14. The drain of the source follower transistor 124 is coupled to a voltage supply (e.g., AVDD). A row select transistor 126 is coupled to a source of the source follower transistor 124. In operation of the image sensor, the row select transistor 126 is coupled to output a data signal (e.g., image data or focus data) from the source follower transistor 124 of pixel 100 to a bit line 112 in response to a row select signal RS.

Referring to FIG. 9, in various examples, some or all of the photodiodes 12-1, 12-2, 12-3, and 12-4 may be configured as image sensing photodiodes included in a color pixel array. In some embodiments, some or all of the photodiodes 12-1, 12-2, 12-3, and 12-4 may be configured as phase detection autofocus photodiodes depending on the specific location of the pixel 100 within the pixel array.

In the present embodiment, as shown in FIG. 9, the incident light that is directed to the photodiodes 12-1, 12-2, 12-3, and 12-4 that are configured as image sensing photodiodes. The incident light is directed through respective color filters of a color filter array before reaching the photodiodes 12-1, 12-2, 12-3, and 12-4. In one embodiment, the color filter array may be a Bayer color filter. Thus, the incident light may be directed through a red color filter, or a green color filter, or a blue color filter before reaching the photodiodes 12-1, 12-2, 12-3, and 12-4 that are configured as the image sensing photodiodes.

In various exemplary embodiments, the incident light that is directed to the photodiodes 12-1, 12-2, 12-3, and 12-4 that are configured as phase detection autofocus photodiodes. The incident light is directed through a microlens prior to reaching the respective photodiodes 12-1, 12-2, 12-3, and 12-4. In the various examples, other than the incident light being directed through either a color filter or through a microlens, the photodiodes 12-1, 12-2, 12-3, and 12-4 may be otherwise substantially similar.

In various exemplary embodiments, the photodiodes of the pixel array including photodiodes 12-1, 12-2, 12-3, and 12-4 are binned. As such, the information generated from each photodiode is summed with information generated from one or more nearby binned photodiodes to generate combined information, and therefore the performance of each individual photodiode is summed up to improve the performance of the pixel array. For instance, in various embodiments, 2×2 groupings of photodiodes (i.e., 4C cells) are configured to be binned such that the 4 photodiodes included in each grouping all share the same spectral response or same color. In other words, the photodiodes are arranged in the pixel array such that each 2×2 grouping of image sensing photodiodes shares a common color filter, e.g., a red color filter, a green color filter, a blue color filter, or an infrared filter. In one embodiment, the 2×2 groupings of binned photodiodes are all adjacent photodiodes in the pixel array and share the same color filter. In one embodiment, the 2×2 groupings of binned photodiodes may not all share the same color. Instead, each two photodiodes that have the same color are separated from one another by another photodiode having a different color.

In various embodiments, the phase detection autofocus photodiodes are grouped in 2×2 groupings, which are interspersed among image sensing photodiodes, share a microlens. In another embodiment, the phase detection autofocus photodiodes are grouped in 2×1 groupings that share a microlens and are interspersed among image sensing photodiodes of a color pixel array.

### OTHER EXAMPLES

In the above described embodiments, the n-type regions of the photodiodes 12 are connected to the floating diffusion region 14 via the transfer transistors 20. The polarity of the above-mentioned configuration may be appropriately inverted. For example, when the FDTI 26 is the n-type, phosphorus (P) or arsenic (As) may be doped.

A pixel transistor shared by a plurality of photodiodes 12 of one pixel, e.g., a reset transistor RST, a row select transistor RS, or a source follower transistor SF may be formed on another semiconductor substrate (transistor substrate). Thereby, the image sensor may be configured by superimposition of substrates. For example, another substrate on which an ASIC for processing output of the transistor substrate is mounted may be separately provided, and the three substrates may be stacked onto each other.

### EFFECTS OF EMBODIMENT

According to the image sensor of the embodiment, crosstalk between the pixels may be effectively suppressed by the BDTIs and the FDTIs. Therefore, blooming may be also suppressed, and full well capacity can be increased.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. An image sensor comprising:
a plurality of pixels; and
deep trench isolations (DTIs) formed between the plurality of pixels, wherein each of the plurality of pixels comprises:
a photodiode,
a floating diffusion region, and
a transfer gate coupling the photodiode and the floating diffusion region, wherein
the deep trench isolations comprise:
back side deep trench isolations (BDTIs) extending from a back surface of a substrate, wherein the BDITs surround the photodiodes and the floating diffusion regions of the plurality of pixels respectively from adjacent pixels defining a pixel region for respective one of the plurality of pixels, and
front side deep trench isolations (FDTIs) extending from a front surface of the substrate and having lower ends facing part of upper ends of the BDTIs.

2. The image sensor according to claim 1, wherein
each of the plurality of pixels has a substantially square shape in a plan view along a direction plane parallel to the front surface of the substrate, and
portions of the BDTIs corresponding to corners pf the pixel region having partial depths with upper ends terminated in a middle portion of the substrate, and the FDTIs are formed to face the upper ends.

3. The image sensor according to claim 2, wherein
portions of the BDTIs other than the corners of the pixel region having full depths extending from the back surface to the front surface of the substrate.

4. The image sensor according to claim 1, wherein the FDTIs and the BDTIs are formed of different materials.

5. The image sensor according to claim 4, wherein each of the FDTIs comprises a polysilicon material, and each of the BDTIs comprises a dielectric material.

6. The image sensor according to claim 1, wherein the photodiode comprises a photodiode doped region having a first conductive type, and
a low-concentration impurity-doped region having a second conductivity type opposite to the photodiode doped region of the first conductivity type disposed adjacent a side surface of the FDTIs is provided.

7. The image sensor according to claim 1, wherein the FDTIs are coupled to receive a ground reference voltage.

8. The image sensor according to claim 1, wherein the low-concentration impurity-doped region includes a portion disposed between the photodiode region and a corresponding front side deep trench isolation (FDTI) included in the FDTIs.

9. The image sensor according to claim 1, wherein each of BDTIs is vertically aligned with a respective one of the FDTs and collectively defines a pixel region of each of the plurality of pixels.

10. The image sensor according to claim 1, wherein a cross-sectional width of a lower end of one of the FDTIs is larger than a cross-sectional width of the upper end of a corresponding one of BDTIs.

11. The image sensor according to claim 1, wherein each of the FDTIs is formed of polysilicon material.

12. The image sensor according to claim 1, wherein a lower end of a respective one of the FDTIs and an upper end of a respective one of the BDTIs are in direct contact.

13. A pixel, comprising:
a photodiode disposed in a semiconductor material having a front side surface and a back surface opposite to the front side surface,
a floating diffusion region disposed in the semiconductor material, and
a transfer gate disposed to couple the photodiode and the floating diffusion region, wherein an isolation structure comprises:
a back side deep trench isolation extending from the back surface of the semiconductor material toward the front side surface of the semiconductor material, wherein back side deep trench isolation surrounds the photodiode and the floating diffusion regions defining a pixel region for the pixel,
wherein the back side deep trench isolation has a first portion located in a corner region of the pixel region and a second portion located in a non-corner region of the pixel region;
wherein the first portion of the back side deep trench isolation has a first depth that is less than a second depth of the second portion of the back side deep trench isolation with respect to the back surface of the semiconductor material.

14. The pixel according to claim 13, wherein the second depth of the second portion is substantially equal to a vertical thickness of the semiconductor material.

15. The pixel according to claim 13, wherein the isolation structure further comprises a front side deep trench isolation extending from the front side surface of the semiconductor material into the semiconductor material, wherein the front side deep trench isolation extends to be in direct contact with the first portion of the back side deep trench isolation.

16. The pixel according to claim 15, wherein the transfer gate comprises a vertical transfer gate extending into the semiconductor material from the front side surface, wherein the vertical transfer gate has a gate depth less than a front isolation depth of the isolation structure.

17. The pixel according to claim 15, wherein the front side deep trench isolation comprises of a trench filled with a polysilicon material with an impurity, and the back side deep trench isolation comprises of a trench at least partially filled with a dielectric material.

18. The pixel according to claim 17, wherein the polysilicon material of the front side deep trench isolation is coupled to receive a ground reference voltage.

19. The pixel according to claim 18, further comprising an impurity-doped region disposed in the semiconductor material surrounding the front side deep trench isolation.

20. The pixel according to claim 19, wherein the impurity-doped region is coupled to the polysilicon material of the front side deep trench isolation to receive the ground reference voltage.
